(19) United States
(12) Patent Application Publication
(10) Pub. No.: US 2023/0268716 A1
(43) Pub. Date: Aug. 24, 2023

(54) NARROW LINEWIDTH LASER WITH FLAT FREQUENCY MODULATION RESPONSE

(71) Applicant: National Research Council of Canada, Ottawa (CA)

(72) Inventors: Grzegorz PAKULSKI, Woodlawn (CA); Mohamed RAHIM, Orleans (CA); Michel MORIN, Quebec (CA); Simon AYOTTE, Saint-Augustin-de-Desmaures (CA); Keven BÉDARD, Quebec (CA); Muhammad MOHSIN, Ottawa (CA)

(21) Appl. No.: 18/017,608

(22) PCT Filed: Jul. 22, 2021
(86) PCT No.: PCT/CA2021/051015

§ 371 Date: Jan. 23, 2023

Related U.S. Application Data
(60) Provisional application No. 63/055,687, filed on Jul. 23, 2020.

(51) Int. Cl. H01S 5/068; H01S 5/125; H01S 5/227; H01S 5/042; H01S 5/22; H01S 5/10; H01S 5/0625

(52) U.S. Cl. CPC H01S 5/06817; H01S 5/125; H01S 5/227; H01S 5/0425; H01S 5/2223; H01S 5/1014; H01S 5/06255; H01S 5/101; H01S 2301/02

(57) ABSTRACT

A laser comprising a narrow linewidth, comprising: a grating along a laser cavity; a laser waveguide having a plurality of waveguide sections corresponding to a plurality of grating sections, each of the plurality of waveguide sections having a ridge/mesa width for detuning the grating in each of the plurality of grating sections; and a plurality of contact electrodes contacting each of the plurality of waveguide sections, the plurality of contact electrodes for applying a different current to each of the plurality of waveguide sections to enable active feedback noise suppression.

### FIELD

The present disclosure relates to narrow linewidth lasers.

### BACKGROUND

Many optical sensors are based on an interferometric effect such as a cavity resonance or diffraction from gratings. Such sensors may be extremely sensitive, however, the achievable sensor performance is limited by the wavelength linewidth and noise of the light source used to interrogate the sensor. Semiconductor lasers are the preferred light source for many optical sensor applications. Commercially available semiconductor lasers have linewidths larger than 100 kHz. Certain next generation optical sensor applications require lasers with linewidth of approximately 1 kHz or less. There are no commercially available stand-alone semiconductor lasers that can achieve low linewidth in the 1 kHz range.

Currently, narrow linewidths are achievable by combining lasers with external resonant cavities. The combination of a semiconductor laser with an external cavity results in a complex assembly that negates the size advantages and simplicity of semiconductor lasers. Such heterogeneous long cavity lasers are also susceptible to mode-hopping that makes the laser unstable and unsuitable for sensor applications.

Redistributing the photon density in the laser cavity, achieved for example by varying the current along the cavity or varying the pitch gratings, has shown some improvement in laser linewidth. Smoothing the photon density in the laser reduces spatial hole burning and increases laser stability. This may be achieved by detuned gratings. However, detuned gratings with a varying periodicity are difficult to fabricate.

The laser linewidth may also be improved by using active feedback to modulate the bias current to suppress the laser wavelength and/or frequency drifts. Because the laser frequency modulation response changes sign at a few hundred kilohertz, active feedback is not feasible for suppressing rapid wavelength and/or frequency fluctuations over a wide frequency range. At high frequencies, these fluctuations would contribute to increasing laser linewidth.

The background herein is included solely to explain the context of the disclosure. This is not to be taken as an admission that any of the material referred to was published, known, or part of the common general knowledge as of the priority date.

### SUMMARY

In accordance with an aspect, there is provided a laser having a narrow linewidth, comprising:
a grating along a laser cavity;
a laser waveguide having a plurality of waveguide sections corresponding to a plurality of grating sections, each of the plurality of waveguide sections having a ridge/mesa width for detuning the grating in each of the plurality of grating sections; and
a plurality of contact electrodes contacting each of the plurality of waveguide sections, the plurality of contact electrodes for applying a different current to each of the plurality of waveguide sections to enable active feedback noise suppression.

In accordance with another aspect, there is provided a method of fabricating a laser having a narrow linewidth comprising:
providing a grating along a laser cavity;
providing a laser waveguide having a plurality of waveguide sections corresponding to a plurality of grating sections, each of the plurality of waveguide sections having a ridge/mesa width for detuning the grating in each of the plurality of grating sections; and
providing a plurality of contact electrodes contacting each of the plurality of waveguide sections, the plurality of contact electrodes for applying a different current to each of the plurality of waveguide sections to enable active feedback noise suppression.

Advantageously, the laser combines:
(i) multiple electrical contacts allowing for a non-uniform bias current distribution and a localized bias current modulation to enable active feedback noise suppression up to very high frequencies,
(ii) a uniform period grating,
(iii) a mesa/ridge with a varying width to detune grating sections and compensate for the effects of longitudinal spatial hole burning, of the carrier density distribution due to injection levels as well as of the temperature distribution along the waveguide sections, and
(iv) a BH laser structure to further reduce the frequency noise.

### BRIEF DESCRIPTION OF THE DRAWINGS

FIG. 1 shows an exemplary schematic drawing for a narrow linewidth laser with feedback;

FIG. 2 shows the dependence of the effective index as a function of the width of an active QW InGaAsP/InP waveguide;

FIG. 3 shows the spectral transmission of a uniform Bragg grating waveguide;

FIG. 4a shows an exemplary top view of a laser with a varying waveguide width comprising a wide center section;

FIG. 4b shows an exemplary top view of a laser with a varying waveguide width comprising a narrow center section;

FIG. 5 shows the gain margin as a function of the index step between the center and end sections;

FIG. 6 shows the transmission spectra of a combined grating (solid line) and a detuned side section grating (dotted line);

FIG. 7a shows an example of a varying width active waveguide used to achieve a narrow linewidth laser comprising a uniform centre section with curved and tapered ends;

FIG. 7b shows an example of a varying width active waveguide used to achieve a narrow linewidth laser comprising a non-uniform centre section with curved and tapered ends;

FIG. 8 shows an example of a varying width active waveguide in which contact lengths do not match the lengths of the waveguide sections;

FIG. 9 shows a comparison of the frequency noise spectra of a free running single contact DFB laser and that of a three-contact varying mesa BH DFB laser;

FIG. 10 shows carrier density and photon density distributions along a 2 mm long laser cavity: L=2 mm, Lc=Lcc=400 um, Ic=20 mA and Is=95 mA each;

FIG. 11 shows the frequency noise and the frequency shift Δf as a function of the injection current applied to the centre contact (L=2 mm, Lc=Lcc=400 um, Is=95 mA each);

FIG. 12 shows the measured amplitude and phase of the FM response, as a function of the injection current modulation frequency, of a single contact laser (dotted lines) and a varying waveguide width BH laser with split electrical contacts (solid lines);

FIG. 13 compares the frequency noise spectra of a free running three-contact varying mesa BH DFB laser and that of the same laser subjected to feedback as in FIG. 1; and

FIG. 14 shows a cut-out cross-section of a varying mesa BH DFB laser.

### DETAILED DESCRIPTION

Unless otherwise explained, all technical and scientific terms used herein have the same meaning as commonly understood by one of ordinary skill in the art to which this disclosure belongs. Although any methods and materials similar or equivalent to those described herein can be used in the practice for testing aspects of the invention, the typical materials and methods are described herein.

It is also to be understood that the terminology used herein is for the purpose of describing particular aspects only and is not intended to be limiting. Patent applications, patents, and publications are cited herein to assist in understanding the aspects described. All such references cited herein are incorporated herein by reference in their entirety and for all purposes to the same extent as if each individual publication or patent or patent application was specifically and individually indicated to be incorporated by reference in its entirety for all purposes. To the extent publications and patents or patent applications incorporated by reference contradict the disclosure contained in the specification, the specification is intended to supersede and/or take precedence over any such contradictory material.

In understanding the scope of the present application, the articles “a”, “an”, “the”, and “said” are intended to mean that there are one or more of the elements. Additionally, the term “comprising” and its derivatives, as used herein, are intended to be open-ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

It will be understood that any component defined herein as being included may be explicitly excluded from the claimed invention by way of proviso or negative limitation.

In addition, all ranges given herein include the end of the ranges and also any intermediate range points, whether explicitly stated or not.

Terms of degree such as “substantially”, “about” and “approximately” as used herein mean a reasonable amount of deviation of the modified term such that the end result is not significantly changed. These terms of degree should be construed as including a deviation of at least ±5% of the modified term if this deviation would not negate the meaning of the word it modifies.

The abbreviation, “e.g.” is derived from the Latin exempli gratia, and is used herein to indicate a non-limiting example. Thus, the abbreviation “e.g.” is synonymous with the term “for example.” The word “or” is intended to include “and” unless the context clearly indicates otherwise.

The following publications are incorporated herein by reference:

[1] Corrugation-Pitch-Modulated Distributed Feedback Lasers with Ultranarrow Spectral Linewidth, M. Okai, M. Suzuki, T. Taniwatari, and N. Chunone, Jpn. J. Appl. Phys. 33, 2563, (1994).

[2] GaInAsP/InP phase-adjusted distributed feedback lasers with a step-like nonuniform stripe width structure, H. Soda, K. Wakao, H.Sudo, T. Tanahashi, H. Imai. Electronics Letters, Vol.20, No. 22 November 1984.

[3] Comparison between ‘power matrix model’ and ‘time domain model’ in modeling large signal responses of DFB lasers, C. F. Tsang, D. D. Marcenac, J. E. Carroll, L. M. Zhang, IEE-Proc. Electron., Vol. 141, No 2, April 1994.

[4] Experimental and theoretical analysis of the carrier induced red-shifted FM-response of λ/4-shifted MQW DFB LD, M. J. Steinmann, R. J. S. Pedersen, and Y. Kotaki, In Proceedings of the 13th IEEE International Semiconductor Laser Conference 1992, Kazagawa, Japan, (pp. 172-173). IEEE.

FIG. 1 shows an exemplary schematic for a narrow linewidth laser with a feedback circuit generally referred to by the number 10. In this embodiment, the circuit 10 comprises a combination laser 12, a beam splitter 21, a frequency-amplitude discriminator 18, a fast photodetector 26, an amplifier/filter 16 and a vector summing unit 14. Optical energy 20 emitted from the laser 12 is split in beam splitter 21 into an output beam 24 and a reference beam 22. Frequency fluctuations in the reference beam are converted to amplitude fluctuations by the frequency-amplitude discriminator 18 and then converted to an electrical signal in the fast photo-detector 26. After amplification in amplifier/filter 16, the electrical signal or feedback signal 17 is combined with the bias signal 15 in the summing unit 14, resulting in signal 45. Signal 45 is then applied to one of the contacts, centre contact 40, of the combination laser 12 in FIG. 1, to counter the spontaneous frequency fluctuations generated in the laser 12 and present in the emitted optical output 20. The other contacts 41 and 42 on the laser 12 are also biased to set the desired operating properties of the laser 12. In the present example, feedback signal 17 is combined with the bias signal applied to the centre contact of a laser 12 with three contacts. It could also be combined with the bias signal applied to a contact at either end of the laser 12. Furthermore, the laser 12 could have two contacts or more than three contacts. In any case, feedback signal 17 is applied to a part of the laser cavity and not over the whole laser 12 length.

The combination distributed feedback (DFB) laser 12 uses a Bragg grating to achieve single mode operation. In one implementation, four special design features are combined to create a semiconductor laser 12 with narrow linewidth and a flat frequency modulation (FM) response. 1) The combination laser 12 uses detuned gratings to achieve single longitudinal mode operation and high side mode suppression ratio (SMSR). 2) Detuned gratings are achieved by a varying mesa/ridge width. The combination laser 12 does not physically change the grating periodicity. Instead the laser waveguide mesa/ridge width is changed along the cavity, while the grating period is constant. Since a change in the mesa/ridge width changes the effective index in the laser waveguide, this produces an equivalent effect to changing grating periodicity. The advantage is that a simple uniform grating fabrication process, like holographic exposure, can be used to make these lasers. 3) It uses multiple contact electrodes. The combination laser 12 design uses split electrode contacts along the laser cavity so that different currents can be independently applied to different laser sections. In one implementation, applying different currents to the laser sections facilitates achieving a dynamic red optical wavelength shift and a flat frequency response of the laser 12. However, a flat FM response may be achieved by other means. 4) The combination laser uses a Buried hetero-structure (BH) design to further reduce the frequency noise.

A conventional DFB laser with a uniform grating period supports two longitudinal modes of equal threshold gain existing around the Bragg stop-band when the laser facets are antireflection (AR) coated. In order to enforce stable single mode operation, phase shifts may be introduced. Another approach uses a grating period adjustment along the laser cavity to locally shift the Bragg wavelength. Since the Bragg wavelength λ_{B}, is defined by the physical grating pitch ∧ and the effective index neff of the waveguide according to: λ_{B}=2*∧*n_{eff}, the shift of the Bragg wavelength can be achieved either by changing the actual grating period or the effective index.

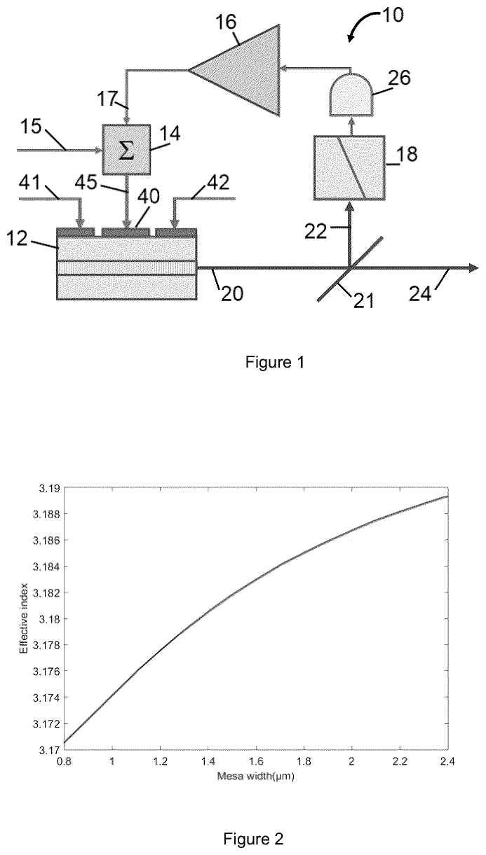

In an implementation, the effective index change resulting from a varying mesa width for modal stabilization is relied upon. The effective index changes noticeably as a function of the mesa width, as shown in FIG. 2. The graph shows the effective index calculated for a 4 QW InGaAsP/InP mesa, with separate confinement and overgrown with InP, as a function of the mesa width. In this approach, the physical grating period A remains constant and the grating can be defined by a simple holographic exposure. From the fabrication point of view, this is easier done than changing the actual period of the grating, which may require e-beam lithography or a grating mask, as used for instance by Okai [1]. Although a varying waveguide width BH DFB laser has been reported in the literature [2], in the present disclosure, the manipulation of the width of the waveguide is used not only to achieve single mode operation but also achieve a low phase noise and therefore a narrow linewidth.

Other than laser sections of different waveguide widths, the present disclosure describes the use of separate electrical contacts for carrier injection into the active waveguide. The number and the length of sections of different waveguide widths do not have to correspond to the number and length of contacts.

Finally, the combination laser 12 in FIG. 1 is a distributed feedback (DFB) laser implemented as a buried hetero-structure (BH) with a buried/overgrown grating in the laser waveguide providing internal optical feedback and enabling stimulated emission. A BH laser has typically a lower frequency noise than a ridge waveguide laser as less spontaneous emission gets coupled to the laser mode.

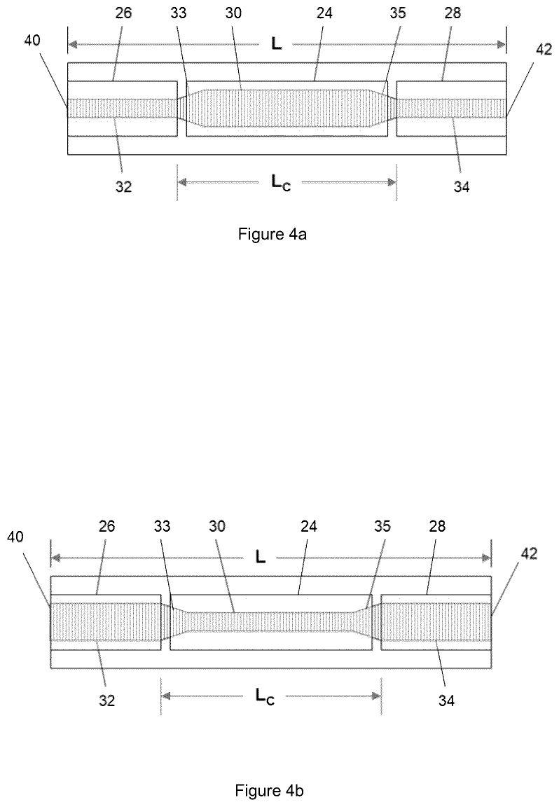

FIGS. 4a and 4b show the top view of devices with a varying waveguide width (not to scale), FIG. 4a shows a varying waveguide width with a wide center section and FIG. 4b shows a varying waveguide width with a narrow center section. The combination laser 12 has multiple contact electrodes 25, 26 and 28, disposed on top of the varying width active waveguide with a uniform grating. In this simple implementation, shown in FIG. 4a, end sections 32 and 34 of the waveguide, have equal width and are narrower than the central section 30. There are also transition regions 33 and 35 between the sections to avoid abrupt changes in the waveguide width to reduce scattering.

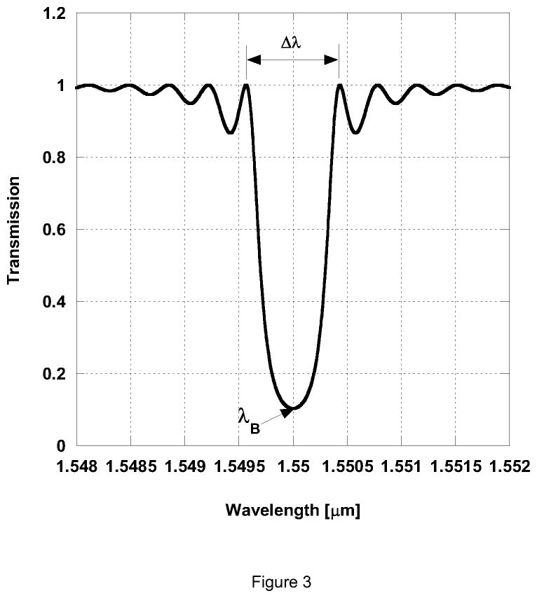

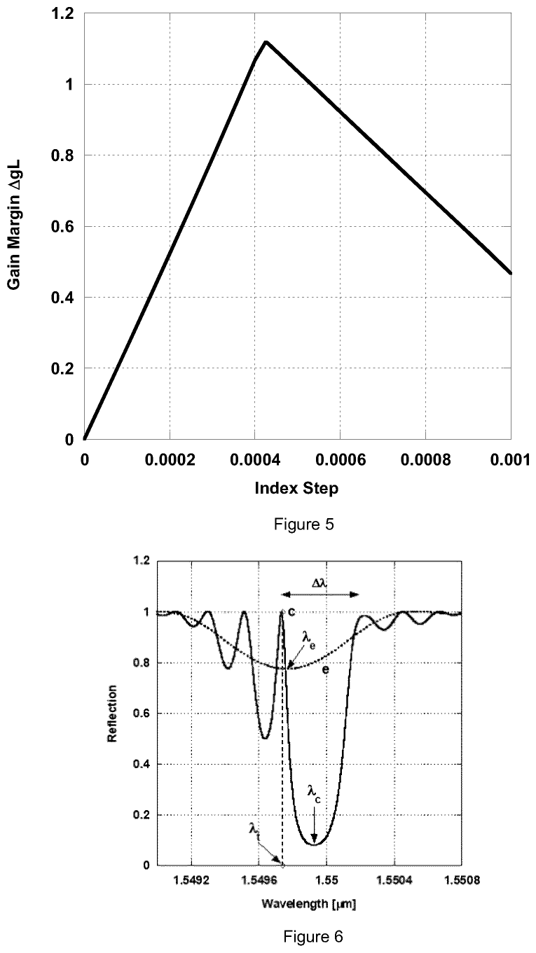

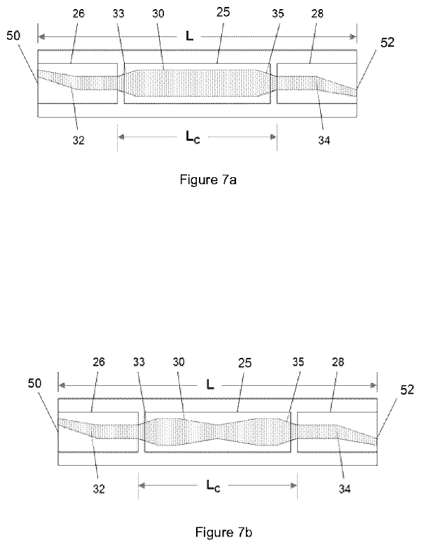

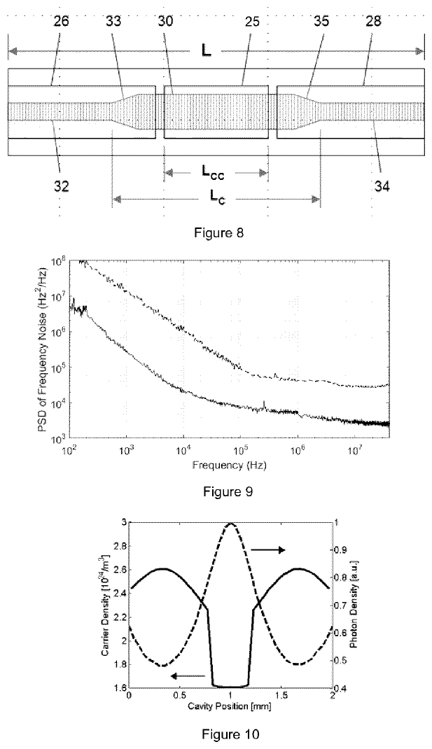

As known in the art, a uniform DFB laser comprising only center section 30 is likely to oscillate simultaneously on two longitudinal modes at wavelengths near the first transmission maxima on either side of the stop-band shown in FIG. 3. Changing the waveguide width locally detunes Bragg wavelength λ_{B} of the waveguide segment and is primarily used to ensure single wavelength emission from the device. The required amount of detuning between the laser sections can be obtained through modeling, e.g. using a transfer matrix model of the cavity. The calculation and design strive to achieve a high gain margin, i.e. a large difference in threshold gains between the two modes of the waveguide with the lowest threshold gains. This ensures single mode operation and a high side mode suppression ratio (SMSR) for the laser 12. FIG. 5 presents the results of such calculations performed for a device configuration with the following properties: a 2 mm long DFB cavity with grating strength κ=9/cm (κL=1.8), and a centre section length of 1 mm and width of 2 μm. Maximum gain margin for this configuration occurs for an index step of 4.3e-4. FIG. 2 shows the dependence of the effective index of a waveguide including a four quantum well waveguide with separate confinement, as a function of the waveguide width. According to this graph, an index step of 4.3e-4 translates to a change in waveguide width of 0.07 μm between the center and end waveguide sections, which is easy to implement. The resulting transmission spectra for the combined cavity (solid line) and the detuned side reflector (dotted line) are presented in FIG. 6. Here, λ_{c} denotes the wavelength of the stopband center of the combined cavity. The stopband center of an end section is marked by λₑ. The transmission spectrum of the combined grating is no longer symmetric, as it was in the case of a uniform DFB laser and illustrated in FIG. 3. The laser 12 with the combined grating oscillates on a single mode at wavelength λₜ, i.e. on the short wavelength side of the combined grating stop-band, as favoured by the side section gratings.

Although the exemplary laser 12 with varying waveguide width in FIGS. 4a and 4b is drawn with three separate contacts, the gain margin and transmission spectra of FIGS. 5 and 6 were calculated as if the contacts were connected together and formed one continuous Ohmic contact. Single contact lasers can achieve stable narrow linewidth operation when the material constituting the active waveguide has a low linewidth enhancement factor, the cavity is long and the coupling coefficient is carefully selected to produce only moderate spatial hole burning (SHB). Unfortunately, the emission from such lasers is not narrow enough for linewidth sensitive applications. To reduce the emission linewidth further, the active feedback shown in FIG. 1 may be used.

In one implementation, the laser 12 may have two or more separate contacts. Then, the detuning between sections, and/or contacts, is influenced not only by the varying mesa width and the effective index change caused by spatial hole burning (SHB), but also by index changes due to different injection levels into the sections via the electrical contacts (contacts 25, 26, and 28 in FIGS. 4a and 4b). Increasing injection levels affect the index of refraction of the waveguide material via a free carrier effect resulting in a reduction of the index. Additionally, increasing injection levels increase the waveguide index through Joule heating. In a symmetric anti-reflective (AR/AR) coated cavity, spatial hole burning manifests itself mostly in the center section because of increased photon density in this location. The increased index step between center and side sections, created by the SHB phenomenon, leads to a decrease in the cavity's gain margin, as can be seen in FIG. 5. Worth noticing in FIG. 5 is the faster decrease in gain margin occurring when the effective index step is decreased. For this reason the opposite index step, i.e. a center section narrower than the end sections as in FIG. 4b, is not as effective for the modal stabilization of single contact lasers. In multi-contact lasers, a narrow centre section configuration can still be useful, e.g. for controlling SHB.

In general, the waveguide width within sections does not have to be uniform and may be varied to compensate or enhance the effects of longitudinal spatial hole burning, carrier density distribution due to injection levels through contacts, as well as temperature distribution along the waveguide sections. Furthermore, the waveguides with gratings can be tapered to transform the mode for better coupling and even curved to reduce residual reflections from the AR-coated facets. Examples of such varying width waveguides are shown in FIGS. 7a and 7b. Similarly, the contacts do not have to coincide with the waveguide sections of the same width. An example of a situation where contact lengths are different from the lengths of the waveguide sections is presented in FIG. 8.

The facets 50, 52 of the combination laser 12 have to be antireflection-coated (AR) so that the feedback is provided only by the grating. Optical power thus comes out from both ends of the laser 12, which is disadvantageous. This is especially troublesome when the laser configuration is symmetrical as in FIGS. 4a and 4b and symmetrically biased, since the output optical power is then evenly divided between both laser facets. The situation can be improved by introducing asymmetry in the laser configuration. For example, the length of section 32 in FIGS. 4a and 4b can be increased in order for the grating found therein to provide a stronger feedback, thus favouring the output of optical power from the opposite side of the laser 12, i.e. through facet 52. This scenario is not preferred when a narrow linewidth is desired, as this increases the field non-uniformity and leads to an increased noise level of the device. Another possibility is to cut the laser 12 in half and coat the newly created facet with a high reflectivity (HR) coating, a procedure amounting to folding the laser cavity. In such devices most of the optical power comes out from the AR-coated facets. For example, the laser 12 in FIG. 4a could be cut in the middle of section 30 and the new facet thus created HR-coated. This, however, introduces uncertainty in the grating phase termination at the HR-coated facet and therefore leads to an unpredictable laser performance, including an unpredictable frequency noise. These lasers have to be carefully characterized and selected before deployment.

The number of contacts along the laser cavity may vary depending on the laser cavity configuration. Symmetric cavity usually requires three contacts. Folded cavity can be sufficiently controlled by only two contacts. Applying different injection current levels to the contacts may suppress spatial hole burning and improve laser stability, suppress side-modes, and thereby maintain the phase noise low.

While one implementation is directed towards constant grating period along the cavity and the varying mesa/ridge width for effectively changing the grating period, other implementations comprise a non-uniform grating along the laser cavity and the varying mesa/ridge width, in co-existence with each other. In general, their coexistence may enhance both modal stability as well as the control of the SHB of the laser 12.

FIG. 9 compares the frequency noise spectrum of a commercial single contact DFB laser with the spectrum of a varying waveguide width laser 12 of FIG. 8. The varying mesa (VM) laser is 3 mm long with a mesa that is 1.9 μm wide at the ends of the cavity and 2 μm wide in the centre (L=3 mm, Lc=900 μm and Lcc=400 μm). The currents applied to the three contacts are (108/25/118) mA. The laser 12 emits light at a wavelength of 1550 nm. The intrinsic frequency noise of the three-contact VM BH DFB laser is as low as 2000 Hz²/Hz at high frequencies corresponding to a Lorentzian linewidth of 6.3 kHz.

Another important property of the narrow linewidth laser is the optical frequency response of the emitted light at different frequencies of modulation of the injection current. In a single contact laser, at low modulation frequencies, the optical frequency decreases (red shift) as the injection current is increased. This results from the temperature of the active layer increasing with the injection current, with a concomitant increase in the effective index of the waveguide and therefore a decrease in the emitted optical frequency. On the other hand, at high modulation frequencies of the injection current, the free carrier effect dominates and an increase in the injection current shifts the emission frequency to higher values (blue shift). Thus, the phase of the emitted optical frequency shift of the single contact laser depends strongly on the injection current modulation frequency. This behaviour is detrimental if the laser is to be used within a feedback loop as shown in FIG. 1. Such a feedback applied to the single contact laser would be useful only at low frequencies where the phase of the frequency response does not change much.

In one example, BH lasers with a varying mesa waveguide structure including a uniform grating and split electrical contacts as illustrated in FIGS. 4a, 4b, 7a, 7b, and 8 have the desired properties. However, a flat FM response may be achieved by other means. As known in the art, by applying the current modulation over a limited portion of the laser, e.g. on only one of the three contacts shown in FIGS. 4a, 4b, 7a, 7b and 8, it is possible to achieve a free carrier FM response that is red shifted. A local increase in the injection current produces a local increase in the carrier density. It also results in an increase in the optical power circulating inside the laser 12 and thus a decrease in the carrier density in the rest of the cavity, a trend opposite to that observed in the section where the current modulation is applied. This explains the phase inversion of the carrier FM response going from blue shifted to red shifted. As a result, the phase of the overall FM response varies much less from low to high modulation frequencies, which affords a more efficient frequency noise reduction with a feedback circuit as shown in FIG. 1.

As known in the art, the red shift effect due to carriers is most visible when a high non-uniformity of carrier density exists along the laser cavity. FIG. 10 displays photon and carrier densities calculated with a finite difference time domain laser model similar to that described in [3] but including also thermal effects. The cavity length L is 2 mm, while the centre section length Lc and the center contact length Lcc are both equal to 400 μm. The end sections, detuned as described above, are biased at 95 mA each and the center contact bias is set at 20 mA. The density of photons peaks at the center of the laser cavity, similarly as in a DFB laser with a phase shift. This peaking comes along with a significant dip in the carrier density due to the stronger saturation. In the present case, a lower current injection level to the center contact further enhances the SHB phenomenon, thus amplifying the contrast in the carrier density profile and the free carrier induced red shift observed when the current applied to the center contact goes up. FIG. 11 shows the calculated dependence of the optical emission frequency as a function of the injection current to the center contact for the same laser (solid line), including both the carrier effect and the thermal effect. The axis on the right shows the frequency shift which represents the difference between the calculated optical frequency and a reference frequency used during the modelling. The optical frequency decreases (red shift) as a function of the current applied to the center contact. The dashed-dotted line shows the contribution of the carrier effects without the thermal effects. It has been generated by setting a very long thermal time constant in the simulation. The increase in the slope observed at low currents on the dashed-dotted line is due to the red shifted carrier FM response getting larger at low currents as aforementioned. At currents lower than 40 mA, the carrier induced frequency change is red shifted while at currents larger than 60 mA, it is blue shifted. The frequency noise dependence for this laser 12 is given by the dashed line. As observed, selecting the bias level on the center contact involves a compromise between getting a larger carrier induced red shifted FM response and a lower frequency noise.

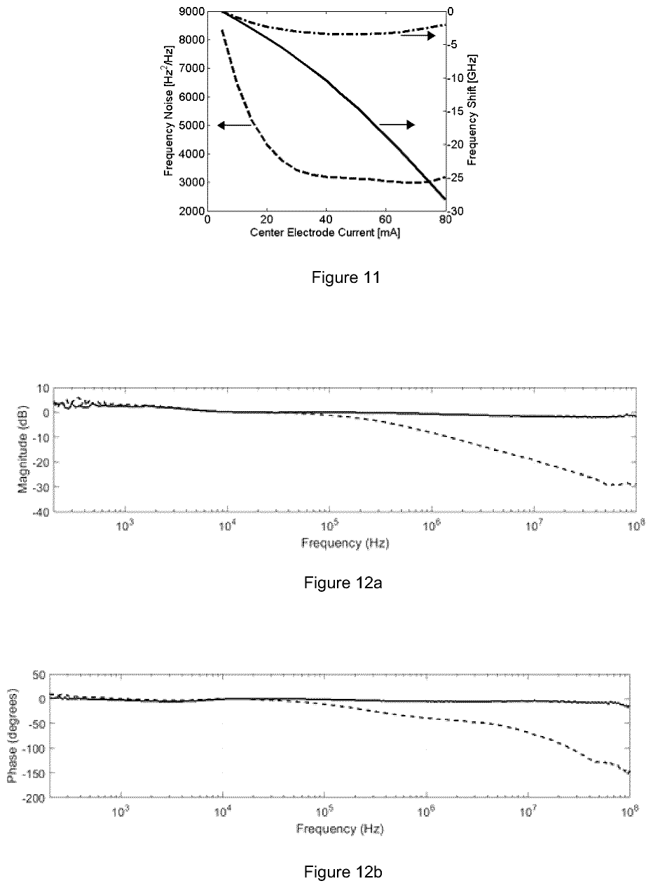

Applying a current modulation to the centre contact section of the laser 12 biased at ˜20 mA results in a high frequency FM response that is free carrier driven and has the same phase as the low frequency FM response driven by temperature. As a result, the overall FM response remains flat from low to high frequencies. This is clearly visible when one compares the amplitude and phase of the FM response of a single contact laser 12 and of a varying waveguide width laser with split electrical contacts that is non-uniformly biased, as shown in FIG. 12. Both the amplitude and phase of the FM response of the single contact DFB laser (dotted lines) dip at frequencies well below 1 MHz, which precludes an efficient frequency noise reduction by means of an electronic feedback. This is in contrast to the varying waveguide width, split contact BH lasers (solid lines), where the FM amplitude and phase remain constant up to 100 MHz. Thus, the frequency noise of varying waveguide width, split contact BH DFB lasers may be reduced by the system shown in FIG. 1, over a much wider frequency range than the frequency noise of their single contact counterparts. The obtained experimental result is comparable to that reported by Steinman et al (FIGS. 4 & 5 in [4]) for a three contact quarter lambda shifted DFB laser.

FIG. 13 compares the frequency noise spectra of a free running three-contact varying mesa BH DFB laser and of the same laser subjected to feedback as in FIG. 1. At 10 MHz the frequency noise of the combination laser 12 with feedback is as low as 5 Hz²/Hz, a nearly 30 dB reduction from the noise of the free running laser.

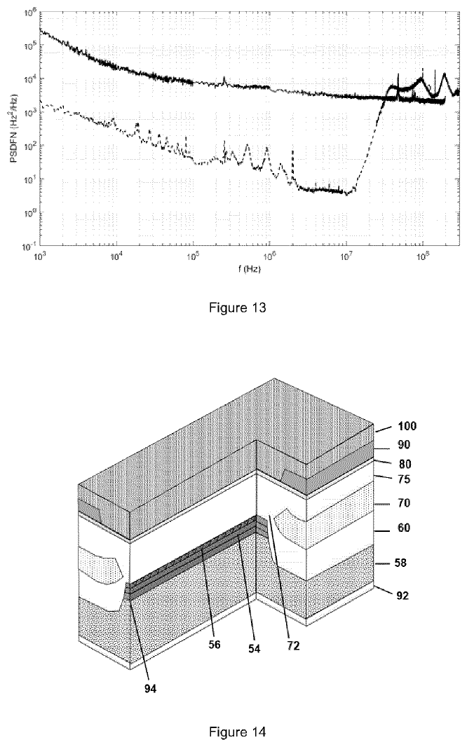

Low noise properties of the combination laser 12 are partially due to the BH environment in which the varying width waveguide is embedded. A cut-out cross-section of a fully processed BH laser is shown in FIG. 14. The buried heterostructure consists of an active waveguide 54 with 2 to 4 quantum wells in a separate confinement heterostructure with a grating layer 56. The structure is grown in a low pressure MOCVD reactor on an n-doped substrate 58. An index-coupled grating is etched into a InGaAsP layer located below or above the quantum well stack and is overgrown with InP. The period of the grating is instrumental in determining the emission wavelength of the laser 12. The waveguide mesa is dry etched and then wet cleaned. During the etching step, the shape of the mesa is defined by a SiO₂ O stripe mask with a varying width. Current blocking p-n-p layers 60, 70 and 72 are then grown around the mesa. Subsequently the SiO₂ stripe mask is removed and the wafer is blanket overgrown with a layer of InP, 75, and finalized with an InGaAs contact layer 80. Further processing involves etching isolation trenches (not shown) on the sides of the mesa to reduce leakage current through the blocking layers, etching electrical isolation between laser contact sections, dielectric passivation 90, contact via etching and deposition of contact metallization 100. After wafer lapping and polishing, an n-contact layer 92 is deposited. The finished wafers are cleaved into bars and the facets 94 are AR-coated. After singulation, individual lasers are bonded onto carriers.

While several aspects of the design features in the combination laser 12 have been described previously, the combination of all of these to create a stand-alone semiconductor laser 12 with intrinsically low noise and flat FM frequency response is novel. The emission linewidth of the laser 12 can be further reduced and stabilized by active feedback.

What is claimed is:

1. A laser having a narrow linewidth, comprising:
a grating along a laser cavity,
a laser waveguide having a plurality of waveguide sections corresponding to a plurality of grating sections, each of the plurality of waveguide sections having a ridge/mesa width for detuning the grating in each of the plurality of grating sections; and
a plurality of contact electrodes contacting each of the plurality of waveguide sections, the plurality of contact electrodes for applying a different current to each of the plurality of waveguide sections to enable active feedback noise suppression.

2. The laser of claim 1, wherein the grating comprises a uniform grating period.

3. The laser of claim 1, wherein the grating comprises a non-uniform grating period.

4. The laser of claim 1, wherein lengths of the plurality of contact electrodes for applying a different current to the plurality of waveguide sections are different from lengths of the plurality of waveguide sections.

5. The laser of claim 1, wherein the laser is a buried heterostructure type device.

6. The laser of claim 1, wherein one of the plurality of waveguide sections at an end of the laser cavity is curved and/or tapered.

7. The laser of claim 1, wherein the ridge/mesa width of one of the plurality of waveguide sections is non-uniform.

8. The laser of claim 1, wherein the plurality of waveguide sections includes a central waveguide section, a first end waveguide section and a second end waveguide section.

9. The laser of claim 8, wherein the central waveguide section comprises a first ridge/mesa width and the first end waveguide section and the second end waveguide section comprise a second ridge/mesa width.

10. The laser of claim 9, wherein the first ridge/mesa width is different from the second ridge/mesa width.

11. The laser of claim 9, wherein the first ridge/mesa width is equal to the second ridge/mesa width.

12. The laser of any one of claims 8 to 11, wherein a length of the first end waveguide section is different from a length of the second end waveguide section.

13. The laser of any one of claims 8 to 11, wherein a length of the first end waveguide section is equal to a length of the second end waveguide section.

14. The laser of any one of claims 1 to 13, wherein the laser cavity is folded by cleaving through a center section of the laser cavity to form a cleaved facet, and wherein the cleaved facet comprises a high reflectivity coating.

15. The laser of any one of claims 1 to 14, wherein the laser is part of an active feedback loop, the active feedback loop comprising the laser, a splitter, an optical frequency discriminator, a photodetector, an amplifier, and a vector sum module.

16. The laser of claim 15, wherein a feedback signal is applied to at least one of the plurality of contact electrodes.

17. The laser of claim 16, wherein the feedback signal applied to one of the plurality of contact electrodes differs from the feedback signal applied to another of the plurality of contact electrodes.

18. A method of fabricating a laser having a narrow linewidth comprising:
providing a grating along a laser cavity;
providing a laser waveguide comprising a plurality of waveguide sections corresponding to a plurality of grating sections, each of the plurality of waveguide sections comprising a ridge/mesa width for detuning the grating in each of the plurality of grating sections; and
providing a plurality of contact electrodes contacting each of the plurality of waveguide sections, the plurality of contact electrodes for applying a different current to each of the plurality of waveguide sections to enable active feedback noise suppression.

19. The method of claim 18, wherein the grating comprises a uniform grating period.

20. The method of claim 18, wherein the grating comprises a non-uniform grating period

21. The method of claim 18, wherein lengths of the plurality of contact electrodes for applying a different current to the plurality of waveguide sections are different from lengths of the plurality of waveguide sections.

22. The method of claim 18, wherein the laser is a buried heterostructure type device.

23. The method of claim 18, wherein one of the plurality of waveguide sections at an end of the laser cavity is curved and/or tapered.

24. The method of claim 18, wherein the ridge/mesa width of one of the plurality of waveguide sections is non-uniform.

25. The method of claim 18, wherein the plurality of waveguide sections comprises a central waveguide section, a first end waveguide section and a second end waveguide section.

26. The method of claim 25, wherein the central waveguide section comprises a first ridge/mesa width and the first end waveguide section and second end waveguide section comprise a second ridge/mesa width.

27. The method of claim 26, wherein the first ridge/mesa width is different from the second ridge/mesa width.

28. The method of claim 26, wherein the first ridge/mesa width is equal to the second ridge/mesa width.

29. The method of any one of claims 25 to 28, wherein a length of the first end waveguide section is different from a length of the second end waveguide section.

30. The method of any one of claims 25 to 28, wherein a length of the first end waveguide section is equal to a length of the second end waveguide section.

31. The method of any one of claims 18 to 30, wherein the laser cavity is folded by cleaving through a center section of the laser cavity to form a cleaved facet, and wherein the cleaved facet comprises a high reflectivity coating.

32. The method of any one of claims 18 to 31, wherein the laser is part of an active feedback loop, the active feedback loop comprising the laser, a splitter, a frequency-amplitude discriminator, a photodetector, an amplifier, and a vector sum module.

33. The method of claim 32, wherein a feedback signal is applied to at least one of the plurality of contact electrodes.

34. The method of claim 33, wherein the feedback signal applied to one of the plurality of contact electrodes differs from the feedback signal applied to another of the plurality of contact electrodes.
